(19) United States
(12) Patent Application Publication
(10) Pub. No.: US 2004/0227246 A1
(43) Pub. Date: Nov. 18, 2004

(54) Semiconductor device

(75) Inventor: Yasuhiro Araki, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Renesas Technology Corp., Tokyo (JP)

(21) Appl. No.: 10/679,355

(22) Filed: Oct. 7, 2003

(30) Foreign Application Priority Data
May 16, 2003 (JP) 2003-139467

(51) Int. Cl. H01L 23/48

(52) U.S. Cl. 257/758

(57) ABSTRACT

A semiconductor device has a semiconductor substrate; a first interlayer insulating film on the semiconductor substrate, and having first contact holes; first contact plugs having portions buried in the first contact holes and portions protruding from the surface of the first interlayer insulating film; sidewalls on the sides of the protruding portions of the first contact plugs; a second interlayer insulating film on the first interlayer insulating film, the first contact plugs, and the sidewalls, and having second contact holes; and second contact plugs in the second contact holes, and connected to the first contact plugs.

### BACKGROUND OF THE INVENTION

1. Field of the Invention

The present invention relates to a semiconductor device having first contact plugs formed in a first interlayer insulating film, and second contact plugs connected to the first contact plugs, formed in a second interlayer insulating film.

2. Background Art

The recent downsizing of semiconductor devices has made multi-layer wiring technique sun avoidable. In such multi-layer wiring techniques, contact plugs for connecting transistors and the like to wirings on interlayer insulating films are formed in the interlayer insulating films.

The contact plugs are formed in two stages to minimize etching margins, and to reduce the size of semiconductor devices. In this case, first contact plugs are formed in a first interlayer insulating film as an LIC (local interconnect), a second interlayer insulating film is formed on the first interlayer insulating film, and second contact plugs are formed in the second interlayer insulating film so as to be connected to the first contact plugs.

However, there was a problem when the second interlayer insulating film was etched to form the second contact plugs, wherein etching might not stop on the first contact plugs due to misalignment, and gate electrodes 3 or the like under the first interlayer insulating film might also be etched. This might cause short-circuiting. To cope with this problem, in a conventional process (e.g., Japanese Patent Application Laid-Open No. 11-204634 (1999) (pp. 2-3, FIG. 12)), a nitride film was formed on the entire surface of the first interlayer insulating film to prevent over-etching.

However, conventional semiconductor devices had a problem that when the semiconductor devices were applied to flash memories, electrons in floating gates could not be extracted by UV radiation due to the presence of the nitride film formed on the entire surface.

### SUMMARY OF THE INVENTION

In order to solve the above-described problems, the object of the present invention is to provide a semiconductor device that can prevent over-etching due to the misalignment of the first contact plugs with the second contact plugs, without forming a nitride film on the entire surface of the first interlayer insulating film.

According to one aspect of the present invention, a semiconductor device includes a semiconductor substrate, a first interlayer insulating film formed on the semiconductor substrate and having first contact holes, first contact plugs each having a portion buried in one of the first contact holes and a portion protruded from the surface of the first interlayer film, sidewalls formed on the sides of the protruded portions of the first contact plugs, a second interlayer insulating film formed on the first interlayer insulating film, the first contact plugs, and the sidewalls, and having second contact holes, and second contact plugs formed in the second contact holes and connected to the first contact plugs.

Other and further objects, features and advantages of the invention will appear more fully from the following description.

### BRIEF DESCRIPTION OF THE DRAWINGS

FIG. 1 is a schematic sectional view illustrating a method for manufacturing a semiconductor device according to the first embodiment of the present invention.

FIG. 2 is a schematic sectional view showing a semiconductor device according to the second embodiment of the present invention.

FIG. 3 is a schematic sectional view showing a semiconductor device according to the third embodiment of the present invention.

### DETAILED DESCRIPTION OF THE PREFERRED EMBODIMENTS

First Embodiment

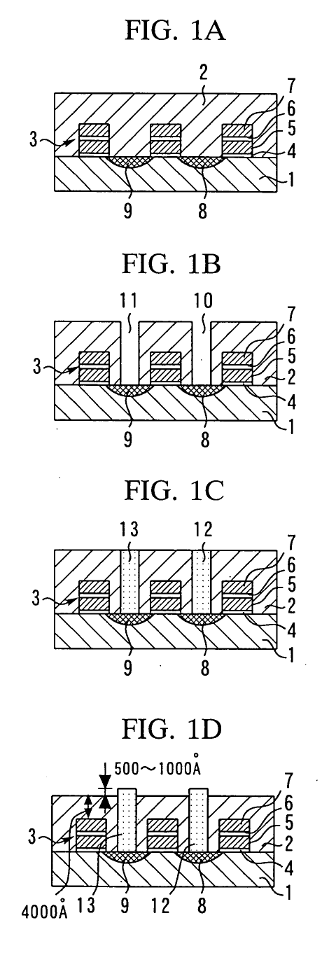

The first embodiment of the present invention will be described below exemplifying that the present invention is applied to the memory cell of a flash memory. FIG. 1 is a schematic sectional view illustrating a method for manufacturing a semiconductor device according to the first embodiment of the present invention. First, as FIG. 1A shows, a first interlayer insulating film 2 composed of an oxide film is formed on a semiconductor substrate 1 whereon the memory cell of a flash memory has been formed. Here, a tunnel oxide film 4, a floating gate 5, an ONO film 6, and a control gate 7 are formed, in this order from the bottom, on the semiconductor substrate 1 as a gate electrode 3. A drain region 8 and a source region 9, which are active regions, are formed in the surface of the semiconductor substrate 1 so as to interleave the gate electrode 3. In other words, active regions are formed in the surface of the semiconductor substrate 1 in the vicinity of the gate electrode 3.

Next, as FIG. 1B shows, the first interlayer insulating film 2 is selectively etched to form first contact holes 10 and 11 of a straight shape on the drain region 8 and the source region 9. Then, as FIG. 1C shows, a wiring material, such as W, Cu, and Ti, is deposited to fill the first contact holes 10 and 11, and CMP (chemical mechanical polishing) is performed to leave the wiring material solely in the first contact holes 10 and 11. Thereby first contact plugs 12 and 13 are formed in the first contact holes 10 and 11, respectively. The first contact plugs 12 and 13 are the source line and the drain line of the memory cell of the flash memory, respectively, and are connected to the drain region 8 and the source region 9, respectively.

Then, as FIG. 1D shows, the first interlayer insulating film 2 is etched by 500 to 1,000 angstroms under the etching condition wherein the etching rate of the first contact plugs 12 and 13 is low (the distance between the surface of the first interlayer insulating film 2 and the gate electrodes 3 becomes 4,000 angstroms), to protrude part of the first contact plugs 12 and 13 from the surface of the first interlayer insulating film 2. Thereby, the first contact plugs 12 and 13 have portions buried in the first contact plugs 12 and 13, and portions protruded from the surface of the first interlayer insulating film 2.

Next, as FIG. 1E shows, an SiN film 14 is deposited by 1,000 to 2,000 angstroms so as to cover the first interlayer insulating film 2 and the first contact plugs 12 and 13. Then as FIG. 1F shows, the SiN film 14 is subjected to anisotropic etching to form sidewalls 15 on the sides of the protruded portions of the first contact plugs 12 and 13.

The sidewalls 15 contact the first interlayer insulating film 2 entirely at the bottom, and have a tapered shape wherein the portion contacting the first contact plugs 12 and 13 is thickest, and thinning apart from the first contact plugs 12 and 13. The lateral width of the sidewalls 15 is larger than the distance between the first contact plugs 12 and 13, and the gate electrodes 3. In other words, the sidewalls 15 partly overlap the gate electrodes 3 when viewed from the top. However, the center portions of the gate electrodes 3 do not overlap the sidewall 15.

Next, as FIG. 1G shows, a second interlayer insulating film 16 of a thickness of 3,000 angstroms is formed on the first interlayer insulating film 2, the first contact plugs 12 and 13, and the sidewalls 15, and planarized. Then, the second interlayer insulating film 16 is selectively etched using the sidewalls 15 as an etching stopper to form second contact holes 17 and 18 of a straight shape. Then, as FIG. 1H shows, a wiring material, such as W, Cu, and Ti, is buried in the second contact holes 17 and 18, and planarized using CMP to form the second contact plugs 19 and 20.

As described above, by using the sidewalls 15 as an etching stopper to etch the second contact holes 17 and 18, over-etching due to misalignment with the first contact plugs 12 and 13 can be prevented. Thereby, no widening of the wiring distance is required to secure the etching margin, and the size of the memory-cell array can be reduced.

Also as described above, since over-etching due to the misalignment of contact plugs can be prevented, the second interlayer insulating film 16 can be thickened. Thereby, when the total film thickness of the first interlayer insulating film 2 and the second interlayer insulating film 16 is constant at 15,500 angstroms, the first interlayer insulating film 2 can be thinned to etch the first contact holes 10 and 11 easily.

By forming the sidewalls 15, the contact holes in the peripheral area other than the memory cell, which pass through both the first interlayer insulating film 2 and the second interlayer insulating film 16, can be etched simultaneously with the etching of the second contact holes 17 and 18, and thus the number of process steps can be decreased. Here, in the case of a flash memory, since there are two stages of the memory-cell gates, and the first interlayer insulating film 2 tends to be thickened, the present invention is particularly effective.

Furthermore, in the present invention, the sidewalls 15 are formed on only the sides of the first contact plugs 12 and 13, but do not cover the entire surface. In other words, the center portion of a gate electrode 3 does not overlap with the sidewalls 15. Therefore, when electrons in the floating gates 5 are extracted by UV radiation, the sidewalls 15 do not interfere. Therefore, the present invention is suited to flash memories.

In addition, although it is most appropriate to apply the present invention to both the contact plugs connected to the drain region 8 and the contact plugs connected to the source region 9 as described above, the present invention may be applied to either one. In such a case, since the width of the source region 9 is normally narrower than the width of the drain region 8, it is preferable to apply the present invention to the contact plugs connected to the source region 9. Although a flash memory is described as an example, the present invention can be applied to other semiconductor devices.

Second Embodiment

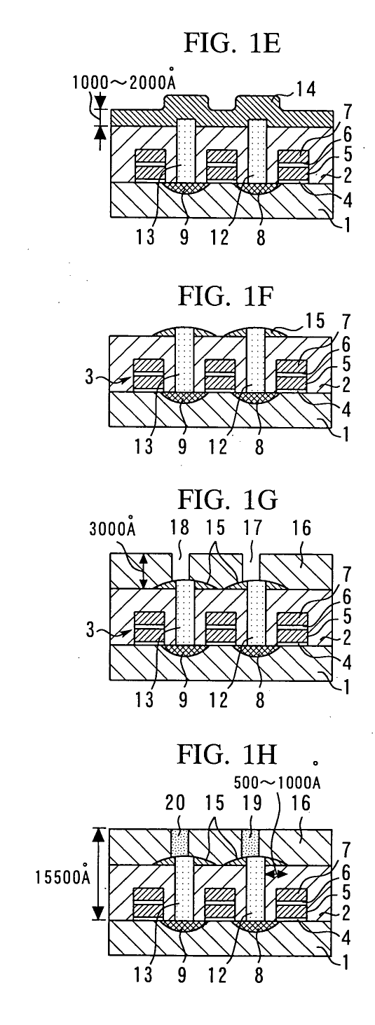

FIG. 2 is a schematic sectional view showing a semiconductor device according to the second embodiment of the present invention. The same constituent elements as in FIG. 1H will be denoted using the same reference numerals, and the detailed description thereof will be omitted. As FIG. 2 shows, the semiconductor device according to the second embodiment has a semiconductor substrate 1; a first interlayer insulating film 2 formed on the semiconductor substrate 1, and having a first contact hole 21 of a downwardly convex funnel shape; a first contact plug 22 formed in the first contact hole 21, and having a downwardly convex funnel shape; a second first interlayer insulating film 16 formed on the first interlayer insulating film 2 and the first contact plug 22, and having a second contact hole 18; and a second contact plug 20 formed in the second contact hole 18, and connected to the first contact plug 22.

Here, the portion of the first contact plug 22 present between two gate electrodes 3 is narrowed, and has a predetermined distance from each gate electrode 3. The portion of the first contact plug 22 present above the gate electrodes 3 is thickened, and partly overlaps with the gate electrodes 3 when viewed from the top. However, the center portions of the gate electrodes 3 do not overlap with the first contact plug 22.

Thereby, as in the first embodiment, the second embodiment also has the effects such as preventing over-etching due to the misalignment of the first contact plugs with the second contact plugs without forming a nitride film on the entire surface of the first interlayer insulating film.

Third Embodiment

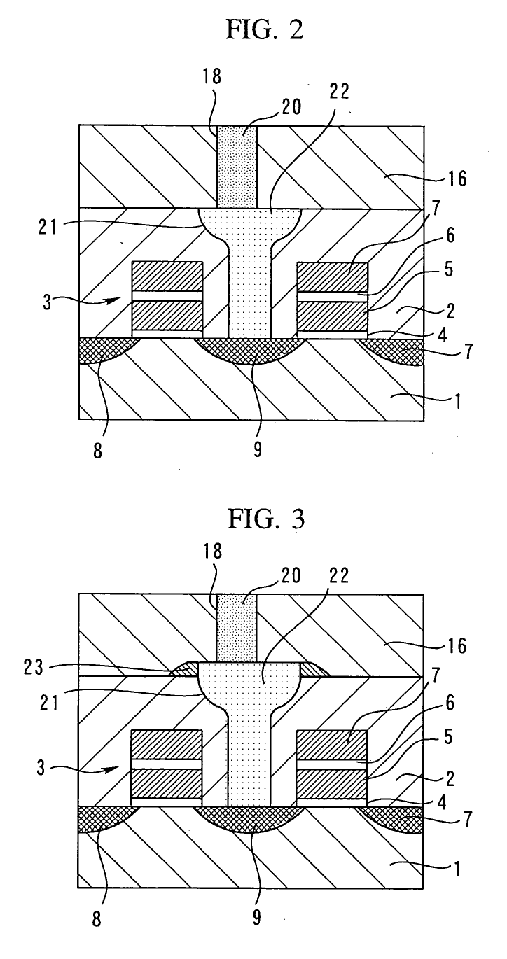

FIG. 3 is a schematic sectional view showing a semiconductor device according to the third embodiment of the present invention. The same constituent elements as in FIG. 1H will be denoted using the same reference numerals, and the detailed description thereof will be omitted. As FIG. 3 shows, the first contact plug 22 having a downwardly convex funnel shape has a portion buried in the first contact hole 21, and a portion protruded from the surface of the first interlayer insulating film 2. A sidewall 23 is formed on the side of the protruded portion.

Here, the sidewall 23 partly overlaps with the gate electrodes 3 when viewed from the top. However, the center portions of the gate electrodes 3 do not overlap with the sidewall 23.

Thereby, as in the first and second embodiments, the third embodiment also has the effects such as preventing over-etching due to the misalignment of the first contact plugs with the second contact plugs without forming a nitride film on the entire surface of the first interlayer insulating film.

The features and advantages of the present invention may be summarized as follows.

As described above, over-etching due to the misalignment of the first contact plugs with the second contact plugs can be prevented without forming a nitride film on the entire surface of the first interlayer insulating film.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2003-139467, filed on May 16, 2003 including specification, claims, drawings and summary, on which the Convention priority of the present application is based, are incorporated herein by reference in its entirety.

1. A semiconductor device comprising:
a semiconductor substrate;
a first interlayer insulating film on the semiconductor substrate and having first contact holes;
first contact plugs, each first contact plug having a portion buried in one of the first contact holes and a protruding portion protruding from the first interlayer film;
sidewalls on the sides of the protruding portions of the first contact plugs;
a second interlayer insulating film on the first interlayer insulating film, the first contact plugs, and the sidewalls, and having second contact holes; and
second contact plugs in the second contact holes and connected to the first contact plugs.

2. The semiconductor device according to claim 1, further comprising:
gate electrodes on the semiconductor substrate; and
active regions in the the semiconductor substrate proximate the gate electrodes, wherein the first contact plugs are connected to the active regions, and lateral width of the sidewalls is larger than distance between the first contact plugs and the gate electrodes.

3. The semiconductor device according to claim 2, wherein the first contact plugs are source lines or drain lines of memory cells of a flash memory, and each of the gate electrodes comprises a control gate and a floating gate of the memory cells.

4. A semiconductor device comprising:
a semiconductor substrate;
a first interlayer insulating film on the semiconductor substrate and having first contact holes;
first contact plugs in the first contact holes, each first contact plug having a downwardly convex funnel shape;
a second interlayer insulating film on the interlayer insulating film and the first contact plugs, and having second contact holes; and
second contact plugs in the second contact holes and connected to the first contact plugs.

5. The semiconductor device according to claim 4, wherein the first contact plugs have portions buried in the first contact holes, and protruding portions protruding from the first interlayer insulating film, and sidewalls on the sides of the protruding portions of the first contact plugs.
